(19) United States
(12) Patent Application Publication
(10) Pub. No.: US 2007/0085126 A1
(43) Pub. Date: Apr. 19, 2007

(54) Circuit board structure and dielectric layer structure thereof

(76) Inventor: Shih Ping Hsu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/544,211

(22) Filed: Oct. 5, 2006

(30) Foreign Application Priority Data
Oct. 17, 2005 (TW) 094136110

(51) Int. Cl. H01L 29/94

(52) U.S. Cl. 257/306

(57) ABSTRACT

A circuit board structure and a dielectric layer structure thereof are proposed. The dielectric layer structure has a dielectric layer and a plurality of bonding particles dispersed in the dielectric layer. The bonding particle is a metal powder particle coated with an insulating film. There is an additional circuit structure formed on the dielectric layer. The dielectric layer structure can be applied to any circuit board, such that the circuit board can be formed with a dielectric layer having bonding particles. The circuit board may form a circuit structure on the dielectric layer, so that the connection between the circuit structure and the dielectric layer can be reinforced by the bonding particles. Therefore, the structures of the present invention can ease the fabrication of forming fine pitch wiring in the circuit board structure, so as to form a circuit structure with finer pitch.

### CROSS-REFERENCE TO RELATED APPLICATION

This application claims benefit under 35 USC 119 to Taiwan Application No. 094136110, filed Oct. 17, 2005.

### FIELD OF THE INVENTION

The present invention is related to circuit board structures and dielectric layer structures thereof, and more particularly, to a dielectric layer structure that can reinforce the connection between a circuit structure and a dielectric layer in a circuit board with finer pitch.

### BACKGROUND OF THE INVENTION

In order to make the semiconductor packages slimmer and smaller in size, it is essential to be able to manufacture products with miniaturized circuit width and electrical connection pad; in other words, the fabrication of fine-pitch products has always been the most urgently pursued goal for the industry.

However, for the purpose of fulfilling the demand of miniaturization and multi-functions for the electronic products, it is necessary to design higher wiring density in the circuit boards or package substrates, and the spacing between each layer has also become increasingly smaller. As a result, the package structure with high wiring density and high pin-count also needs to have its circuit width reduced. Because of this, as the spacing between each circuit continue to reduce, the strength of connection between the circuit structure and the dielectric layer will be weakened.

In order to solve the above problem, the usual solution utilized by the industry is to form a rough surface on top of dielectric layer, so that the connection between the dielectric layer and the circuit structure can be reinforced. FIG. I is the schematic cross-sectional view depicting a circuit board structure with fine pitch according to prior arts. As shown in the figure, a dielectric layer 12 is formed on a surface of a core board 10 having electrical connection pads 101, wherein a plurality of openings 120 are formed on the electrical connection pads 101 in the dielectric layer 12, such that the electrical connection pads 101 of the core board 10 are exposed. Further, a rough surface 14 is formed on the surface of the dielectric layer 12 by having the dielectric layer 12 that has been formed with openings 120 undergoes a desmearing process; and a circuit structure 16 is formed on the dielectric layer 12 having the rough surface 14, wherein the circuit structure 16 comprises a seed layer 161 serving as the conductive pathway, and a circuit layer 162 formed on top of the seed layer 161, such that the seed layer 161 of the circuit structure 16 can be firmly attached to the dielectric layer 12 via the rough surface 14. Furthermore, the patterned circuit layer 162 is formed by electroplating on top of the seed layer 161 in accordance with the prior techniques employed by the industry. For the circuit board structure that is manufactured by such technique, the circuits that are wider than; for example, 20 μm or more, can have better strength of connection, and the influence of antenna effect from the rough surface 14 on electricity is relatively smaller.

However, in the aforementioned circuit board structure with fine pitch, when the width of the circuit becomes smaller than 15 μm or less, the uneven surface of the rough surface 14 will become large indentation or gap to the comparatively smaller circuit structure 16, and thus creates an unfavorable condition for the formation of the circuit structure 16 on the rough surface 14 of the dielectric layer 12 of the circuit board structure. Moreover, as the circuit structure 16 is prone to form irregular shape on the surface that is too rough and uneven, problems such as the occurrence of indentation, gap, and miniscule hole in the circuit structure 16 will be arose. Consequently, the spacing between each circuit cannot be continually reduced, which leads to lower yield and worse electrical performance or functionality of the circuit board. The rough and uneven surface of the circuit structure 16 can also result in antenna effect that enhances the occurrence of noises and other serious electrical problems.

Therefore, the urgent issue to be addressed at the stage is how to provide a dielectric layer used in a circuit board with fine pitch, that can prevent the problem of weak connection between a seed layer and a dielectric layer in the circuit structure of prior arts; as well as the failure to meet the demand of continual reduction of spacing between circuits, lower yield, and worse electrical functionality of the circuit board.

Solutions to these problems have been long sought but prior developments have not taught or suggested any solutions and, thus, solutions to these problems have long eluded those skilled in the art.

### SUMMARY OF THE INVENTION

In light of the drawbacks of the above prior arts, the main objective of the present invention is to provide a circuit board structure and a dielectric layer structure thereof, wherein the dielectric layer is dispersed with bonding particles, and the connection between the circuit structure and the dielectric layer is reinforced by the bonding particles, thereby facilitating the fabrication of fine pitch wiring. Another objective of the present invention is to provide a circuit board structure and a dielectric layer structure thereof that can elevate yield and the electrical performance and functionality of the circuit board.

In accordance with the foregoing and other objectives, the present invention provides a dielectric layer structure of the circuit board, and the dielectric layer structure comprises: at least a dielectric layer; and a plurality of bonding particles, which are evenly dispersed in the dielectric layer, wherein each of the bonding particles is a metal powder particle coated with an insulating film. In the sequential fabricating processes, the surface of the dielectric layer is further processed to remove parts of the insulating film from the surface of the bonding particles, such that at least a portion of the surface of the metal powder particles can be exposed. The metal powder particles can then be connected to the circuit structure by chemical bonding, thereby fortifying the connection and the bonding strength between the circuit structure and the bonding particles and facilitating the fabrication of fine pitch wiring.

The present invention also provides another circuit board structure and a dielectric layer structure thereof in accordance with another embodiment of the present invention, and the circuit board structure comprises: a core board; a least a dielectric layer formed with a plurality of bonding particles, the dielectric layer being formed on a surface of the core board; and a circuit structure comprising a seed layer and a circuit layer formed on top of the seed layer, such that the seed layer mounted on a surface of the dielectric layer and some of the bonding particles contact with the seed layer to reinforce strength of connection between the circuit layer and the dielectric layer. Further, each of the bonding particles may be a metal powder particle coated with an insulating film. The surface of the dielectric layer can be chemically or physically processed to expose the metal powder particle within the bonding particle. Preferably, the chemical processing method can either be desmearing or micro-etching; and the physically processing method can either be plasma etching, reactive ion etching, abrasion, or scrubbing.

Therefore, the dielectric layer structure to be used in the circuit board with fine pitch relies on the bonding particles to serve its purpose; the bonding particles are filled and dispersed evenly in the dielectric layer, and each bonding particle comprises a metal powder particle and an insulating film formed around the surface of metal powder particles. In the sequential fabrication processes, the surface of the dielectric layer is further processed to remove parts of the insulating film from the surface of the bonding particles, so that a portion of the surface of the metal powder particles can be exposed to allow the exposed metal powder particles to provide bonding similar to that of the circuit structure, such that the metal powder particles can be bound to the circuit structure to fortify the connection between the bonding particles and the circuit structure, thereby facilitating the fabrication of fine-pitch wiring. As a result, in the present invention, the dielectric layer of the circuit board with fine pitch has bonding particles protruding from its surface, which imparts better strength of connection to the dielectric layer. Hence problems resulted from the prior arts can be overcome, such as the formation of irregular surface on dielectric layer due to desmearing, and the occurrence of indentation, gap, and miniscule hole in circuit layer. Therefore, the fabrication of the circuit board with fine pitch can be facilitated, the yield can be increased, and the electrical performance, functionality and reliability of the circuit board can be improved.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

The present invention can be more fully comprehended by reading the detailed description of the preferred embodiments listed below, with reference made to the accompanying drawings, wherein:

FIG. 1 is a schematic cross-sectional view showing a circuit board structure of the prior art, which has a fine-pitch structure;

FIG. 2 is a schematic cross-sectional view showing a circuit board structure and a dielectric layer structure thereof, according to the present invention;

FIG. 3 is a schematic cross-sectional view illustrating a structure of a bonding particle contained in the dielectric layer of FIG. 2; and

FIG. 4 shows another embodiment of a dielectric layer structure in accordance with the present invention.

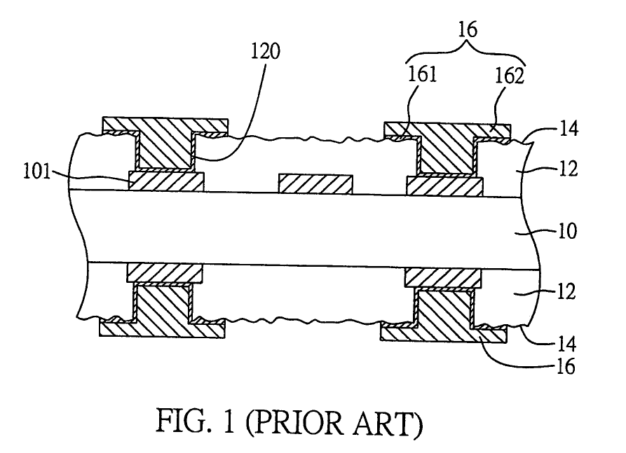

### DETAILED DESCRIPTION OF THE PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawing FIGs. Similarly, although the views in the drawings for ease of description generally show similar orientations, this depiction in the figures is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

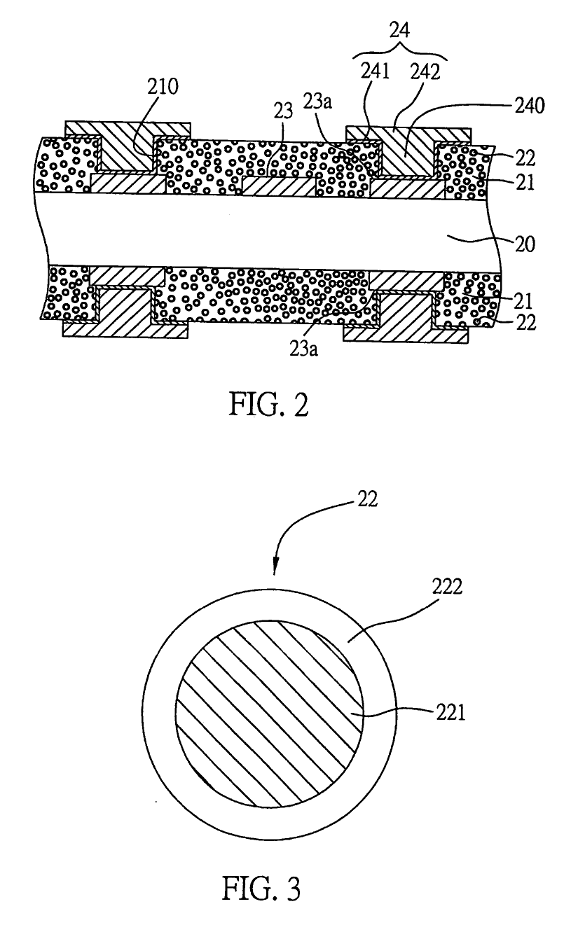

FIG. 2 is a schematic cross-sectional view depicting a circuit board structure with fine pitch according to the present invention. In a circuit board structure, a surface of a core board 20 is formed with a circuit structure 23 and a dielectric layer 21 disposed thereon, wherein the circuit structure 23 has a plurality of electrical connection pads 23a, and the dielectric layer 21 is formed with a plurality of openings 210 to expose portions of the circuit structure 23 that are connected with the electrical connection pads 23a of an upper layer and a lower circuit layer of the circuit structure 23.

An additional circuit structure 24 is formed on top of the dielectric layer 21, wherein the circuit structure 24 is electrically connected to the electrical connection pads 23a of the circuit structure 23 by a plurality of conductive structures 240, wherein the conductive structures 240, each of which can be a conductive via, are formed in the openings 210 of the dielectric layer 21. Each circuit structure 24 comprises a seed layer 241 that serve as a conductive pathway and a circuit layer 242 formed on top of the seed layer 241. As a commonly known technique in the industry, the seed layer 241 is employed to allow a patterned circuit layer 242 to be formed thereon by electroplating. Because the methods used for making the additional circuit structure 24 and the conductive structures 240 are well known by those skilled in the art, it therefore are not further described hereinafter.

Further, the dielectric layer 21 comprises a plurality of bonding particles 22 that are well dispersed within it, and the dielectric layer 21 is formed on the surface of the core board 20 so as to cover the circuit structure 23 underneath it.

FIG. 3 is a cross-sectional view illustrating a structure of a bonding particle 22 contained in the dielectric layer 21 of FIG. 2. As shown in the figure, the bonding particle 22 is made by forming an insulating film 222 around the surface of a metal powder particle 221 (or a metal powder particle with oxidized surface), wherein the insulating film 222 is made of insulating resin film, or preferably, of heat-resistant organic materials. Although, the bonding particle may be made by forming the insulating film around the surface of the metal powder particle, it should be noted that the form of the bonding particle may vary and should not be limited to that described and illustrated. For instance, the bonding particle may be a metal powder that is enclosed with a layer of insulating film; or formed by uniting more than one metal powder particles, each of which is coated with a layer of insulating film.

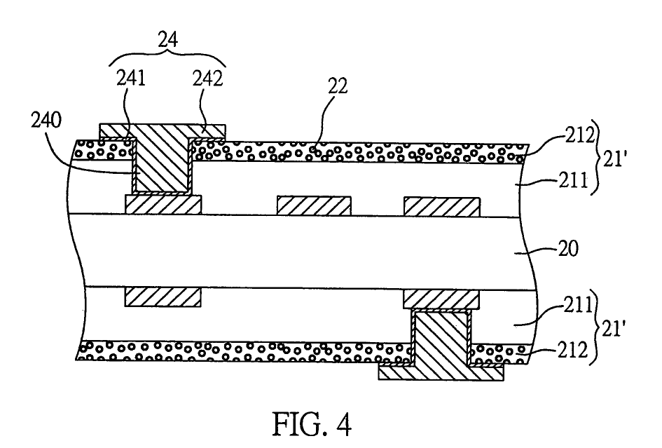

Referring to FIG. 4, showing another embodiment of a dielectric layer structure in accordance with the present invention, a dielectric layer structure 21′ comprises a first dielectric layer 211 covering the surface of the core board 20 and a second dielectric layer 212 formed on top of the first dielectric layer 211. Further, the second dielectric layer 212 comprises evenly dispersed bonding particles 22, such that the dielectric layer structure 21′ can be formed on top of core board 20. In this embodiment, as the bonding particles 22 are contained in the second dielectric layer 212 above the first dielectric layer 211, the strength of connection of bonding particles 22 comes from the connection between the seed layer 241 in the circuit structure 24 on top of the second dielectric layer 212 and the second dielectric layer 212 can be reinforced by the bonding particles 22, so that it is possible to save cost of production and materials.

During the sequential fabrication processes, the surface of dielectric layer 21 to be used for adding extra layers is chemically and physically processed, so that the bonding particles 22 are exposed from the dielectric layer 21 (or as in another embodiment, wherein the bonding particles 22 are exposed from the second dielectric layer 212), such that the insulating film 222 may be removed from the surface of the bonding particles 22 and the surface of metal powder particles 221 may be exposed so as to facilitate the fabrication of fine-pitch wiring. Preferably, the chemical processing method may either be desmearing or micro-etching; and the physically processing method may either be plasma etching, reactive ion etching, abrasion, or scrubbing.

In a preferred embodiment, the metal powder particles 221 (or the metal powder) may be made of a material selected from the group consisting of copper (Cu), nickel (Ni), gold (Au), titanium (Ti), lead (Pd), aluminum (Al), magnesium (Mg), chromium (Cr), and any alloy of the foregoing metals. A preferable diameter of the metal powder particles particle is less than 2 μm. As a result, the bonding particles 22 contained in the dielectric layer 21 or the second dielectric layer 212 will not result in excessively rough surface of the dielectric layer 21, thereby solving problems resulted from excessive roughness of a dielectric layer surface in the prior arts, such as the occurrence of indentation, gap, and miniscule hole in circuit structure. Moreover, the metal powder particles and the seed layer of the circuit structure are of similar metal bonding, which imparts better strength to the connection between the seed layer and the dielectric layer in the circuit structure, and thus the desired strength of connection can be achieved even if the surface of the dielectric layer is not very rough. On the other hand, because the roughness on the surface of dielectric layer is reduced significantly, the occurrence of noises can be lowered, which in turn leads to improved yield and better electrical functionality and reliability of circuit board.

In comparison to the prior arts, the circuit board structure and the dielectric layer structure thereof of the present invention is different in that the dielectric layer is filled and evenly dispersed with bonding particles, and the roughness of the surface of dielectric layer is reduced due to the smaller diameter of metal powder particles in the bonding particles, therefore the disadvantage of excessive roughness on the surface of dielectric layer in the prior arts can be overcome as a result. On the other hand, the metal powder particles can bind to the seed layer of the circuit structure because the two have similar metal bonding, so the connection between the dielectric layer and the seed layer of the circuit structure can be reinforced, which facilitates the implementation of fabricating fine-pitch wiring in a circuit board structure, and improves the yield and the electrical performance, functionality and reliability of circuit board.

Accordingly, the present invention not only solves drawbacks of the prior art, but also provides processes and configurations for read, efficient, and economical manufacturing, application, and utilization.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters set forth herein or shown in the accompanying drawings are to be interpreted in an illustrative and non-limiting sense.

What is claimed is:

1. A dielectric layer structure, comprising:
at least a dielectric layer; and
a plurality of bonding particles, which are evenly dispersed in the dielectric layer, wherein each of the bonding particles is a metal powder particle coated with an insulating film.

2. The dielectric layer structure of claim I, wherein the dielectric layer comprises a first dielectric layer and a second dielectric layer formed on top of the first dielectric layer.

3. The dielectric layer structure of claim 2, wherein the second dielectric layer of the dielectric layer contains a plurality of bonding particles.

4. The dielectric layer structure of claim 1, wherein the metal powder particles are coated with oxidized surface.

5. A circuit board structure, comprising:
a core board;
a least a dielectric layer formed with a plurality of bonding particles, the dielectric layer being formed on a surface of the core board; and
a circuit structure comprising a seed layer and a circuit layer formed on top of the seed layer, such that the seed layer mounted on a surface of the dielectric layer and some of the bonding particles contact with the seed layer to reinforce strength of connection between the circuit layer and the dielectric layer.

6. The circuit board structure of claim 5, wherein the bonding particle is a metal powder that is enclosed with a layer of insulating film.

7. The circuit board structure of claim 5, wherein the bonding particle is a metal powder particle with oxidized surface that is enclosed with a layer of insulating film.

8. The circuit board structure of claim 5, wherein a plurality of openings are formed in the dielectric layer to expose a plurality of electrical connection pads of the circuit structure.

9. The circuit board structure of claim 5, wherein the circuit structure further comprises a plurality of conductive structures formed in a plurality of openings of the dielectric layer, such that the circuit structure is electrically connected to a plurality of electrical connection pads of the circuit structure.

10. The circuit board structure of claim 5, wherein the dielectric layer further comprises a first dielectric layer and a second dielectric layer formed on top of the first dielectric layer.

11. The circuit board structure of claim 10, wherein the second dielectric layer of the dielectric layer contains a plurality of bonding particles.

12. The circuit board structure of claim 10, wherein the surface of the second dielectric layer is treated with at least one of a chemical processing method and a physical processing method, such that metal powder particles within the bonding particles are exposed.

13. The circuit board structure of claim 12, wherein the physical processing method is a process selected from the group consisting of plasma etching, reactive ion etching, abrasion, and scrubbing.

14. The circuit board structure of claim 12, wherein the chemical processing method is a process selected from the group consisting of desmearing and micro-etching.

15. The circuit board structure of claim 5, wherein the surface of the dielectric layer is treated with at least one of a chemical processing method and a physical processing method, such that metal powder particles within the bonding particles are exposed.

16. The circuit board structure of claim 15, wherein the physical processing method is a process selected from the group consisting of plasma etching, reactive ion etching, abrasion, and scrubbing.

17. The circuit board structure of claim 15, wherein the chemical processing method is a process selected from the group consisting of desmearing and micro-etching.
